(19) United States
(12) Patent Application Publication
(10) Pub. No.: US 2010/0163819 A1
(43) Pub. Date: Jul. 1, 2010

(54) RESISTIVE MEMORY DEVICE AND METHOD FOR FABRICATING THE SAME

(76) Inventor: Yun-Taek Hwang, Gyeonggi-do (KR)

Correspondence Address: IP & T Law Firm PLC, 7700 Little River Turnpike, Suite 207, Annandale, VA, 22003, US

(21) Appl. No.: 12/476,279

(22) Filed: Jun. 2, 2009

(30) Foreign Application Priority Data
Dec. 29, 2008 (KR) 10-2008-0135658

(51) Int. Cl. H01L 47/00; H01L 21/16

(52) U.S. Cl. 257/2; 438/104; 257/E21.078; 257/E47.001

(57) ABSTRACT

A resistive memory device and a fabrication method thereof are provided. The fabrication method includes: providing a substrate; forming a lower electrode over the substrate; forming a variable resistive material layer over the lower electrode; forming an ion implantation region to a predetermined depth from a surface of the variable resistive material layer by implanting metal ions or oxygen ions to the surface of the variable resistive material layer; and forming an upper electrode over the variable resistive material layer including the ion implantation region.

### CROSS-REFERENCE TO RELATED APPLICATIONS

The present invention claims priority of Korean patent application number 10-2008-0135658, filed on Dec. 29, 2008, the disclosure of which is incorporated by reference herein in its entirety.

### BACKGROUND OF THE INVENTION

The present invention relates to a technology for fabricating a semiconductor device, and more particularly, to a resistive memory device utilizing resistance variation such as non-volatile Resistive Random Access Memory (ReRAM), and a method for fabricating the same.

Recently, researchers are studying to develop next-generation memory devices that can replace Dynamic Random Access Memory (DRAM) and flash memory. Among them is a resistive memory device using a variable resistive material. The resistive memory device is capable of switching between at least two different resistive states as resistance varies drastically according to an applied voltage. As for the resistive material having such characteristic, a binary oxide containing a transition metal oxide or a perovskite-based material is used.

The structure and the switching mechanism of the resistive memory device are as follows.

A resistive memory device generally includes an upper electrode, a lower electrode, and a variable resistive material layer disposed between the upper electrode and the lower electrode. When predetermined levels of voltages are applied to the upper electrode and the lower electrode, a filamentary current path may be created due to vacancy in the variable resistive material layer or the vacancy may be removed to thereby eliminate a pre-formed filamentary current path according to the applied voltages. The variable resistive material layer takes on one of two different resistance states according to whether the filamentary current path is created or removed. To be specific, the creation of the filamentary current path indicates that the variable resistive material layer takes on a low resistance, which is referred to as ‘set operation’ hereafter. On the contrary, the removal of the filamentary current path indicates that the variable resistive material layer takes on a high resistance, which is referred to as ‘reset operation’ hereafter.

For the resistive memory device to stably acquire the switching characteristics required as a memory device, such problems as excessively high reset current, long reset time, uneven distribution of set/reset current should be solved.

### SUMMARY OF THE INVENTION

Embodiments of the present invention, which are devised to solve the problems of conventional technology, are directed to providing a resistive memory device that can reduce the amount of reset current and reset time and uniformly distribute set/reset current to thereby acquire stable switching characteristics as a memory device by forming an ion implantation region on the surface of a variable resistive material layer, and a method for fabricating the same.

In accordance with an aspect of the present invention, there is provided a method for fabricating a resistive memory device, which includes: providing a substrate; forming a lower electrode over the substrate; forming a variable resistive material layer over the lower electrode; forming an ion implantation region to a predetermined depth from a surface of the variable resistive material layer by implanting metal ions or oxygen ions to the surface of the variable resistive material layer; and forming an upper electrode over the variable resistive material layer including the ion implantation region.

In accordance with another aspect of the present invention, there is provided a resistive memory device, which includes: a substrate; a lower electrode over the substrate; a variable resistive material layer disposed over the lower electrode and having an ion implantation region where oxygen ions or metal ions are implanted to a predetermined depth from a surface of the variable resistive material layer; and an upper electrode over the variable resistive material layer.

In accordance with yet another aspect of the present invention, there is provided a method for fabricating a resistive memory device, which includes: providing a substrate; forming a lower electrode over the substrate; forming a variable resistive material layer over the lower electrode; forming an ion implantation region to a predetermined depth from a surface of the variable resistive material layer by implanting metal ions or oxygen ions to the surface of the variable resistive material layer, wherein the ion implantation region has a lower oxygen or metal vacancy than a region of the variable resistive material layer below the ion-implantation region; and forming an upper electrode over the variable resistive material layer including the ion implantation region.

### BRIEF DESCRIPTION OF THE DRAWINGS

FIGS. 1A and 1C are cross-sectional views describing a resistive memory device and a fabrication method thereof according to an embodiment of the present invention.

### DESCRIPTION OF SPECIFIC EMBODIMENTS

Other objects and advantages of the present invention can be understood by the following description, and become apparent with reference to the embodiments of the present invention.

Referring to the drawings, the illustrated thickness of layers and regions may be exaggerated to facilitate explanation. When a first layer is referred to as being “on” a second layer or “on” a substrate, it includes a meaning that the first layer is formed directly on the second layer or the substrate, or that a third layer may exist between the first layer and the substrate. Furthermore, the same or like reference numerals represent the same or like constituent elements, although they appear in different embodiments or drawings of the present invention.

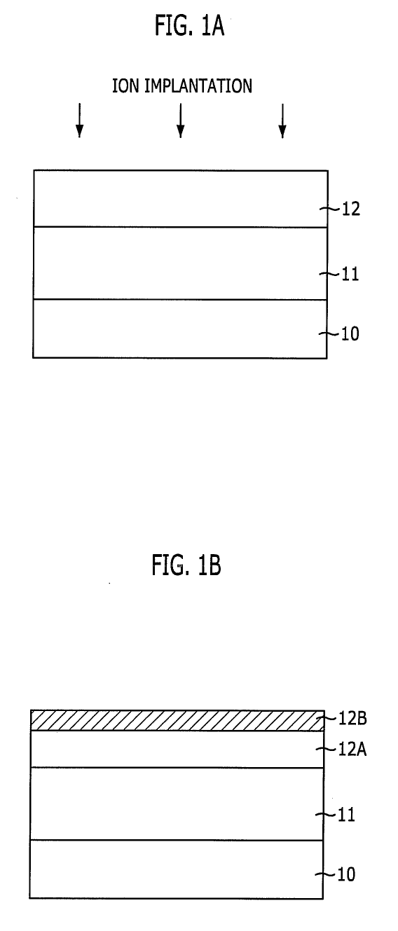

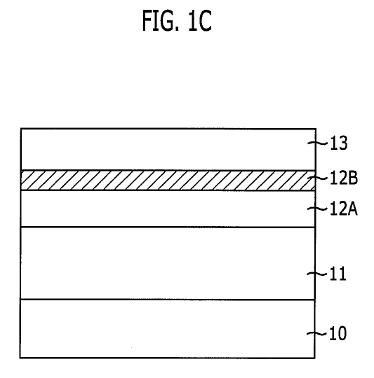

FIGS. 1A and 1C are cross-sectional views describing a resistive memory device and a fabrication method thereof according to an embodiment of the present invention.

Referring to FIG. 1A, a lower electrode 11 is formed over a substrate 10 with a predetermined lower structure. The lower electrode 11 may be formed of platinum (Pt), nickel (Ni), tungsten (W), gold (Au), silver (Ag), copper (Cu), titanium (Ti), zinc (Zn), aluminum (Al), tantalum (Ta), ruthenium (Ru), iridium (Ir), or an alloy thereof, or it may be formed of metal nitride.

Subsequently, a variable resistive material layer 12 is formed over the lower electrode 11. The variable resistive material layer 12 may include a transition metal oxide, such as transition metal oxide, such as nickel monoxide (NiO), titanium dioxide (TiO₂), zinc dioxide (ZnO₂), cobalt monoxide (CoO), hafnium dioxide (HfO₂), zirconium dioxide (ZrO₂), niobium pentoxide (Nb₂O₅), magnesium monoxide (MgO), alumina (Al₂O₃), and tantalum oxide (Ta₂O₅). The variable resistive material layer 12 includes vacancy, e.g., oxygen vacancy or metal vacancy.

Subsequently, oxygen ions or metal ions are implanted into the surface of the variable resistive material layer 12. Herein, the metal ions may be ions of titanium (Ti), zinc (Zn), cobalt (Co), nickel (Ni), aluminum (Al), gold (Au), platinum (Pt), or silver (Ag).

After the ion implantation, thermal treatment may be performed additionally. The thermal treatment may be performed in the atmosphere of oxygen, nitrogen or nitrogen oxide.

Referring to FIG. 1B, an ion implantation region where oxygen ions or metal ions are implanted from the surface of the variable resistive material layer 12 to a predetermined depth is formed as a result of the ion implantation. Hereafter, the ion implantation region of the variable resistive material layer 12 will be denoted by a reference numeral ‘12B’ in the drawings, and the other region without ions implanted therein, which will be referred to as a ion non-implantation region, will be denoted by a reference numeral ‘12A.’

The ion implantation region 12B in the upper part of the variable resistive material layer 12 has a lower vacancy density than the ion non-implantation region 12A. This is because the implanted oxygen ions or metal ions fill the oxygen vacancy or metal vacancy in the variable resistive material layer 12. When the ion implantation region 12B in the upper part of the variable resistive material layer 12 has a lower vacancy density than the ion non-implantation region 12A, there are following advantages.

The creation or removal of a filamentary current path in the variable resistive material layer 12 is originated from the vacancy in the variable resistive material layer 12, which is already described before. The creation of the filamentary current path begins from the lower electrode 11, whereas the removal of the filamentary current path begins from an upper electrode. Therefore, when the ion implantation region 12B has a low vacancy density, the number of created filamentary current paths is small. Thus, it is easy to remove vacancy, that is, pre-created filamentary current paths. Consequently, the amount of reset current and reset time are reduced considerably, and since abnormal set/reset operation is decreased, even distribution of set/reset current is improved.

Referring to FIG. 1C, an upper electrode 13 is formed over the ion implantation region 12B in the upper part of the variable resistive material layer 12. The upper electrode 13 may be formed of platinum (Pt), nickel (Ni), tungsten (W), gold (Au), silver (Ag), copper (Cu), titanium (Ti), zinc (Zn), aluminum (Al), tantalum (Ta), ruthenium (Ru), iridium (Ir), or an alloy thereof, or it may be formed of metal nitride.

As a result of the process shown in FIGS. 1A to 1C, a resistive memory device having the structure shown in FIG. 1C is obtained. When predetermined levels of voltages are applied to the lower electrode 11 and the upper electrode 13 to operate the resistive memory device, the amount of reset current and reset time are reduced remarkably and the set/reset current is evenly distributed, as mentioned in the above.

Although not shown, the substrate 10 may include a transistor as a switching device, and the lower electrode 11 may be connected to a source/drain region of the transistor through a contact plug.

Also, although not illustrated either, the shapes of the lower electrode 11 and the upper electrode 13 may be modified. To take an example, at least one of the lower electrode 11 and the upper electrode 13 may be of a plug type.

According to the embodiments of the present invention, a resistive memory device can reduce the amount of reset current and reset time and uniformly distribute set/reset current to thereby acquire stable switching characteristics as a memory device by forming an ion implantation region on the surface of a variable resistive material layer, and a method for fabricating the same.

While the present invention has been described with respect to the specific embodiments, it will be apparent to those skilled in the art that various changes and modifications may be made without departing from the spirit and scope of the invention as defined in the following claims.

What is claimed is:

1. A method for fabricating a resistive memory device, comprising:
providing a substrate;
forming a lower electrode over the substrate;
forming a variable resistive material layer over the lower electrode;
forming an ion implantation region to a predetermined depth from a surface of the variable resistive material layer by implanting metal ions or oxygen ions to the surface of the variable resistive material layer; and
forming an upper electrode over the variable resistive material layer including the ion implantation region.

2. The method of claim 1, wherein the variable resistive material layer includes a transition metal oxide.

3. The method of claim 1, wherein the forming of the ion implantation region includes:
performing a thermal treatment after ion implantation.

4. The method of claim 1, wherein the metal ions are ions of titanium (Ti), zinc (Zn), cobalt (Co), nickel (Ni), aluminum (Al), gold (Au), platinum (Pt), or silver (Ag).

5. The method of claim 1, wherein at least one of the lower electrode and the upper electrode is of a plug type.

6. A resistive memory device, comprising:
a substrate;
a lower electrode over the substrate;
a variable resistive material layer disposed over the lower electrode and having an ion implantation region where oxygen ions or metal ions are implanted to a predetermined depth from a surface of the variable resistive material layer; and
an upper electrode over the variable resistive material layer.

7. The resistive memory device of claim 6, wherein the variable resistive material layer includes a transition metal oxide.

8. The resistive memory device of claim 6, wherein the metal ions are ions of titanium (Ti), zinc (Zn), cobalt (Co), nickel (Ni), aluminum (Al), gold (Au), platinum (Pt), or silver (Ag).

9. The resistive memory device of claim 6, wherein at least one of the lower electrode and the upper electrode is of a plug type.

10. The resistive memory device of claim 6, wherein resistance of the variable resistive material layer varies as filamentary current paths inside the variable resistive material layer are created or existing filamentary current paths are removed according to voltages applied to the lower electrode and the upper electrode.

11. A method for fabricating a resistive memory device, comprising:
providing a substrate;
forming a lower electrode over the substrate;
forming a variable resistive material layer over the lower electrode;
forming an ion implantation region to a predetermined depth from a surface of the variable resistive material layer by implanting metal ions or oxygen ions to the surface of the variable resistive material layer, wherein the ion implantation region has a lower oxygen or metal vacancy than a region of the variable resistive material layer below the ion-implantation region; and
forming an upper electrode over the variable resistive material layer including the ion implantation region.

12. The method of claim 11, wherein the variable resistive material layer includes a transition metal oxide.

13. The method of claim 11, wherein the forming of the ion implantation region includes:
performing a thermal treatment after ion implantation.

14. The method of claim 11, wherein the metal ions are ions of titanium (Ti), zinc (Zn), cobalt (Co), nickel (Ni), aluminum (Al), gold (Au), platinum (Pt), or silver (Ag).

15. The method of claim 11, wherein at least one of the lower electrode and the upper electrode is of a plug type.
